(19) United States
(12) Patent Application Publication
(10) Pub. No.: US 2012/0177230 A1
(43) Pub. Date: Jul. 12, 2012

(54) SOUND MANAGEMENT DEVICE

(75) Inventor: Charles Kingsley Cooper, Essex (GB)

(73) Assignee: ORANGE MUSIC ELECTRONIC COMPANY LIMITED, Hertfordshire (GB)

(21) Appl. No.: 13/070,559

(22) Filed: Mar. 24, 2011

(30) Foreign Application Priority Data
Jan. 6, 2011 (GB) 1100169.0

(51) Int. Cl. H03F 99/00

(52) U.S. Cl. 381/120

(57) ABSTRACT

A unitary sound management device including an analog amplification system (36) for amplifying an analog sound signal and electronic equipment for the storage and manipulation of digital data, and at least one speaker (6). The analog amplification system (36) is directly connected to the at least one speaker (6) and is also connected to the electronic equipment which, in turn, is connected to the at least one speaker (6). The analog amplification system (36) and the electronic equipment are both provided in a casing and are adapted to be used in combination with each other to provide improved recordal and post-production of sound signals or can be used independently from each other.

### FIELD

This present disclosure relates to a sound management device. The present disclosure also relates to the integration of an analog sound amplification system with electronic equipment for the storage and manipulation of data. Examples of electronic equipment include, but are not limited to, computers, servers, desktop computers, laptops netbooks, and personal digital assistants (PDAs). Similarly, the present disclosure also relates to a conventional data processing device, such as a computer or other electronic device examples of which are given above, having an analog sound amplification device.

### BACKGROUND

An analog sound amplification system is an electrical system with the basic function of amplifying an analog signal that is representative of a sound signal. Analog sound amplification systems come in a range of different physical sizes, different power ranges and different component arrangements but in all cases the amplification system comprises an input for an analog sound signal, an electrical circuit to process the sound signal and an output such as for connection to one or more loudspeakers. The sound amplification system may be housed in a cabinet separate from the loudspeakers with which it is connected, an example of which is described in US 2006133625. Alternatively, a single housing may be used to contain both the sound amplification system and the loudspeakers such as the amplification systems described in US 2006159291 and FR 2539540 which also describes how the action of the loudspeakers may be used to cool amplification components within the housing.

In use, sound generated, for example by an electric guitar, is converted to an analog sound signal by a transducer and transmitted to the input of the sound amplification system. The sound could be generated by any number of instruments, including, but not limited to, an electric guitar, a microphone, an electric keyboard, electric drums and any acoustic instrument to which a transducer is connected. From the input of the sound amplification system, the analog sound signal is transmitted to the amplification circuit. The amplification circuit amplifies the analog sound signal to a power level sufficient to drive the loudspeakers and the amplified analog sound signal is then communicated to the loudspeakers which convert the analog sound signal back into sound waves.

Whilst signal distortion in analog amplification systems can be greatly reduced using various conventional means, it is a feature that is present to a greater or lesser extent in all analog amplification systems.

Analog sound amplification systems have been improved over the years to include multiple controls to enable users to precisely manage the analog amplified sound signal produced by the system. For example, the controls may be used for attenuating high-frequency signals or for manipulating the gain of the amplification circuit, both of which can reduce signal distortion in the output.

Although reference is made above to the amplification of analog sound signals, sound amplification systems which amplify digital sound signals also exist, for example portable integrated amplifiers and speakers for use with solid state music storage devices such an Ipod™. Simple digital sound amplification systems are generally considered inferior to analog amplification systems because of the loss of data arising from the analog to digital conversion process.

A Music Instrument Digital Interface system (MIDI system) is now available for installation on conventional computers and such like, which is used in the recordal and post-production of sound signals. The sound signals may be input to the computer via a Universal Serial Bus (USB) port or another conventional input port. Computers are digital systems and therefore differ at a fundamental level from analog systems. Accordingly, it is necessary to first convert an analog sound signal supplied to the inlet/outlet (I/O) port of a computer to a digital sound signal using an analog-to-digital converter (A/D).

All sound amplification systems introduce some degree of delay between the original generation of a sound signal and the sound signal's reproduction by a loudspeaker. Such delays are usually reported in terms of the latency of the amplification system and more recent developments in sound amplification focus on minimising this delay. The latency of analog amplification systems is traditionally low but the latency of digital sound amplification systems can be much greater. The latency of a digital amplification system arises, in part, as a result of the time taken to convert the analog signal into a digital signal. Actions carried out by the CPU, such as adding or manipulating the digital signal, further contribute to the overall latency of a digital amplification system.

Accordingly, a need exists for a device capable of performing sound amplification, reproduction, recordal and manipulation with a high degree of accuracy.

### SUMMARY OF THE INVENTION

A sound management device comprising a casing in which is mounted an analog amplification system, a data processor and at least one speaker, the analog amplification system being directly connected to the at least one speaker and also being connected to the data processor which, in turn, is connected to the at least one speaker, whereby the analog amplification system can be used in combination with or independently from the data processor to amplify an analog sound signal.

In various embodiments the casing comprises one or more air inlets and an exhaust fan, wherein the sound management device further comprises a first air channel provided within the casing, the first air channel extending from the one or more air inlets in the casing to the exhaust fan, with the rear of at least one speaker in contact with or forming part of a boundary wall of the first air channel to expose air in the first air channel to vibrations generated by the rear of the speaker and at least a part of the data processor being in thermal communication with the first air channel whereby heat generated by the data processor may be dissipated by means of air flow in the first air channel.

In various embodiments the at least one speaker and the exhaust fan are positioned on opposing sides of the casing. Ideally, the one or more speakers are centered in the bottom middle of the front of the sound management device and the exhaust fan is centered in the bottom middle of the back of the sound management device. Ideally, the air flow path along the first air channel is arranged to pass over the hottest parts of the sound management device for example the motherboard of the data processor and, if added by a user, a graphics card.

Furthermore, the first air channel may include a baffle positioned between the at least one speaker and the exhaust fan to at least reduce the transmission of vibrations from the rear of the speaker to the exhaust fan. The baffle may, for example, be formed of one or more electronic components mounted in the casing.

In further various embodiments one or more further air channels providing additional air flow connections between additional air inlets and the first air channel may be provided.

The one or more speakers used in the sound management device may be more powerful than those normally found with conventional data processing devices, such as, but not limited to, computers, servers, desktop computers, laptops, netbooks, and PDAs. For example, the sound management system may include two 35W speakers. Furthermore, by ensuring the rear of at least one speaker is in contact with or forms part of a boundary wall of the first air channel, as the power supplied to the speaker is increased the air flow in the first air channel delivers an increased cooling effect.

Moreover, the casing of the sound management device may be made of wood to provide a better quality of amplified sound than is commonly available from speakers mounted in a conventional computer casing. Also, in further various embodiments an aerial is mounted on the wooden casing for wireless connection to the internet. The aerial may be a Wi-Fi antenna or other antenna for wireless connectivity. This arrangement ensures there is no, or very little, metal adjacent the aerial to disrupt the signal which ensures the wireless signal reception is better than is commonly available with a conventional Wi-Fi antenna mounted in a metal computer tower.

By careful arrangement of the various components of the sound management device within the casing to minimise the amount and the length of cabling used and by selective configuration of the components, the latency of the sound management device can be minimised.

In further various embodiments the sound management device includes an A/D for interfacing between the analog amplification system and the data processor. The inclusion of the A/D enables digital sound signals from the data processor to be converted into analog sound signals, which can then be amplified and reproduced by the analog amplifier and speakers. The A/D is in various embodiments positioned in the casing remote from some or all of the data processor and the other data processing components so as to prevent or minimise the risk of digital interference in the conversion process from these components.

In further various embodiments the sound management device includes a plurality of I/O ports one or more of which may be connected directly to the analog amplification system, one or more of which may be connected to the A/D and one or more of which may be connected to the data processor. This enables the analog amplification system and the speakers to be operated independently of the data processor.

### BRIEF DESCRIPTION OF THE DRAWINGS

Various embodiments will now be described by way of example only with reference to the accompanying drawings, in which:

FIG. 1 is a perspective view of a sound management device in accordance with the present disclosure, with details of the interior visible;

FIG. 2 is a perspective view of the rear of the sound management device of FIG. 1, with details of the interior visible; and

FIG. 3 is a perspective view of the interior of the sound management device of FIG. 1.

### DETAILED DESCRIPTION OF A EXEMPLARY EMBODIMENTS

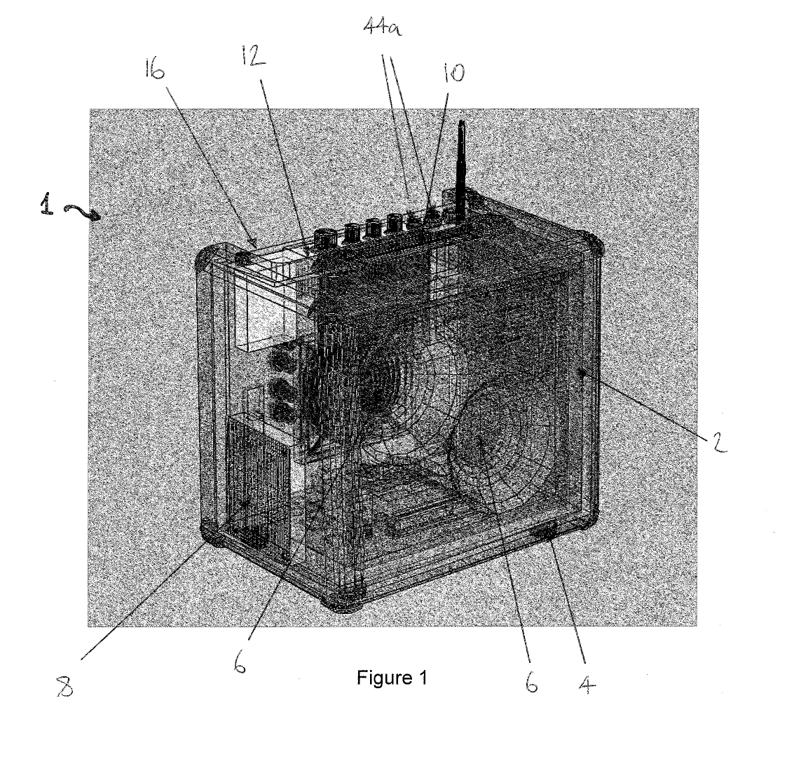

With reference to FIG. 1, there is shown a sound management device in the form of a combined computer and analog sound amplification system 1 which is housed in a cabinet or casing 2. The casing 2 in various embodiments are made from wood, or a material having similar sound characteristics, so as to deliver high quality sound reproduction from the speakers (described below) and to limit the transmission of undesirable vibrations. The casing 2 is supported at its base by one or more sound-absorbing feet 4, which in various embodiments are made of rubber or a similar sound-absorbing material. The feet 4 serve to support the casing 2 away from the surface on which it stands and also serve to prevent movement of the casing 2 during use. The left side of the casing 2 (the left side of FIG. 1) has an air intake 8, which allows air to flow from the surrounding environment into the casing 2 through one or more openings (the air intake 8 illustrated in the figures comprises a grill with a plurality of openings). A handle or grip 10 for use in carrying the casing 2 is positioned on the top surface of the casing 2.

A chassis 16 is provided within the casing 2 along with one or more magnetic speakers 6 positioned at the front of the casing 2 (two speakers are illustrated in the figures). The speakers in various embodiments are 35W speakers, but higher or lower powered speakers are also envisaged. The casing 2 is open to the rear and this in combination with a cut-out section in the top side of the casing 2, positioned rearward of the grip 10, define an aperture 12 that exposes part of the chassis 16 and some of the internal electronic components. The chassis 16 supports the various electrical and electronic components forming the sound management device. To assist comprehension, the chassis 16 has been divided arbitrarily into three regions: an upper region 14 which is partially exposed by the cut-out section in the top side of the casing 2; a middle region 18 immediately below the upper region 14; and a lower region 20 positioned above and in contact with the base of the casing 2. The chassis 16 is secured to the casing 2 by means of suitable fastenings (not shown). The fastenings may be, for example, in the form of screws with two screws fastening the upper region 14 of the chassis 16 to the casing 2; and, two further screws fastening the lower region 20 of the chassis 16 to the casing 2.

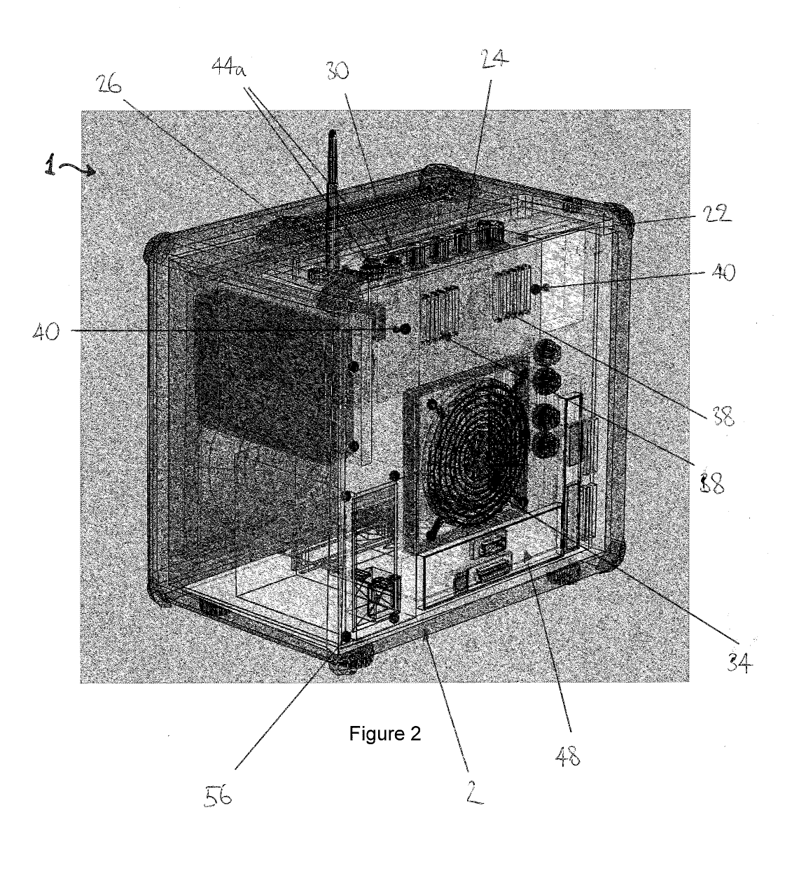

With reference to FIG. 2, a control panel 22 is mounted to the upper region 14 of the chassis 16 and is located in the aperture 12 in the casing 2. The control panel 22 comprises one or more user manipulated analog switches 24 (four switches are shown in the figures) for controlling the output of the speakers 6. The control panel 22 may further include indicators 26, for example in the form of one or more lights, for indicating whether the sound management device is powered, along with one or more USB ports, one or more first jack ports 44a and an aerial 32 (described in further detail later). The control panel 22 also includes an opening to an optical disk drive 30 mounted in the upper region 14 of the chassis 16. The optical disk drive 30 which in various embodiments is, but is not limited to, a slot loading drive is adapted to receive optical disks, such as CD-ROMs or DVDs.

An exhaust fan 34 is mounted to the middle and lower regions 18, 20 of the chassis 16 and is encased by two grills. One of the two enclosing grills is mounted to the exposed rearward side of the sound management device providing the exhaust fan 34 with protection from untoward external interference. The second of the two grills is mounted on the inside of the chassis 16 and protects the exhaust fan 34 from interference from, for example, internal wires that may have moved during transit.

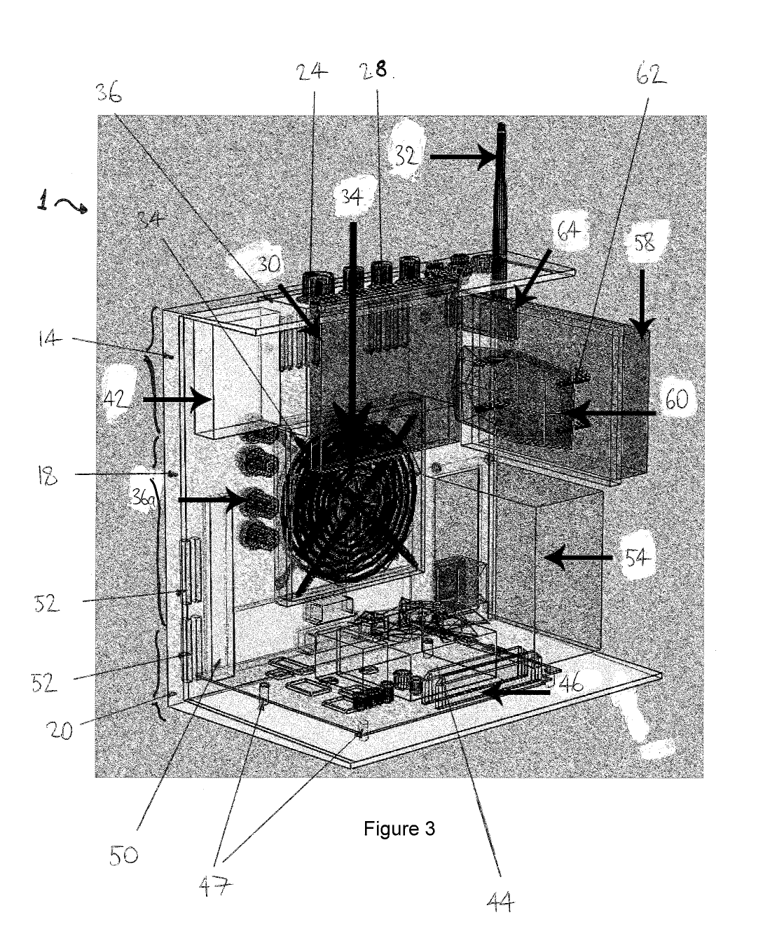

With reference to FIG. 3, amplifier circuitry 36 is located immediately below the control panel 22 in the upper region 14 of the chassis 16. The amplifier circuitry 36 is positioned between the optical disk drive 30 and the rear exposed surface of the upper region 14 of the chassis 16 which has a series of openings 38 positioned above the grill of the exhaust fan 34. The proximity of the openings 38 to the amplifier circuitry 36 means heat produced by the amplifier circuitry 36 during use can be dissipated efficiently. The series of openings 38 also act to ensure that cooling air is able to circulate through the sound management device in the event that other openings (see below) become blocked. The amplifier circuitry 36 is secured in position by means of one or more suitable fixings 40 such as screws (two are shown in the FIG. 3) which fasten the amplifier circuitry 36 to the upper region 18 of the chassis 16. Rotatably mounted control connections 28 respectively extend from each of the analog switches 24 to the amplifier circuitry 36 and are used to communicate to the amplifier circuitry 36 any manually selected control adjustments. The control connections 28 also act as additional fastenings for fixing the amplifier circuitry 36 in its position.

Further jack ports 36a (four are illustrated in the figures) are provided on the rear of the sound management device adjacent the exhaust fan 34. These further jack ports 36a are connected directly to the analog amplifier circuitry 36 and the output of the amplifier circuitry 36 is, in turn, connected to the speakers 6. In use, an analog sound signal supplied to one or more of the further jack ports 36a is fed as an analog sound signal to the amplifier circuitry 36 where it is amplified. Once the analog sound signal has been amplified to a user selected power level sufficient to drive the speakers 6, the analog sound signal is fed to the speakers 6 where it is converted into sound waves. Thus, using the further jack ports 36a the amplification and reproduction of the input sound signal remains at all times analog.

The chassis 16 further includes an A/D 42 and a data processing device for data storage and manipulation such as a conventional CPU 44 and associated data storage. The A/D 42 converts analog sound signals from the jack ports 44a into digital sound signals that can be processed by the CPU 44. It will be appreciated that the A/D 42 may additionally be used to convert digital sound signals into analog sound signals. The A/D 42 is positioned in the upper region 14 of the chassis 16 towards the rear and is mounted by means of one or more fixings such as screws (not shown).

The CPU 44 is located on a motherboard 46, from where it manages other components including any peripherals. The motherboard 46 is secured to the lower region 20 of the chassis 16 using conventional fixings and is supported above the base of the lower region 20 by means of risers 47, which are positioned between the motherboard 46 and the base of the lower region 20. The risers 47 ensure that there is a space between the motherboard 46 and the base of the lower region 20 so that the underside of the motherboard 46 is accessible to a cooling airflow. The fixings and the risers 47 are positioned to facilitate the easy removal and replacement of the motherboard 46, if necessary. With reference to FIG. 2, an I/O panel 48 of the motherboard 46 is accessible at the rear of the sound management device below the grill covering the exhaust fan 34. The I/O panel 48 may include the usual collection of I/O ports and peripheral connectors to be expected with a conventional data processing device including, but not limited to, one or more USB ports, PS/2 connecters, VGA/DVI/HDMI ports, a SPDIF Out, an eSATA interface and multiple audio I/O ports.

The middle region 18 of the chassis 16 further includes a bracket 50, which is in proximity to the motherboard's peripheral component interconnect express (PCI-E) port (not shown). The bracket 50 is secured to the middle and lower sections 18, 20 of the chassis 16, in various embodiments using a single screw. Removal of the bracket 50 provides access to the interior of the chassis 16 for the installation of an optional device that makes use of the motherboard's PCI-E port. Such an optional device could be a dedicated graphics card or a firewire interface, for example. The optional device is mounted to the internal surface of the bracket 50 to prevent movement of the optional device from its assigned position within the chassis.

A further series of openings 52 are located in the middle and lower sections 18, 20 of the chassis 16 between the bracket 50 and a side edge of the casing 2. The proximity of the openings 52 to the motherboard's PCI-E port means that heat produced by any optional device using the PCI-E port can be dissipated efficiently. The openings 52 also act to ensure that cooling air is able to circulate through the electronic device in the event that the other openings 38 become blocked.

A power supply unit (PSU) 54 supplies power to the motherboard 46 and all of the motherboard's associated components, but not directly to the amplifier circuitry 36. The PSU 54 is positioned adjacent the motherboard 46 in the middle and lower sections of the chassis 16 and is secured to the chassis 16 by way of one or more fixings (four screws are shown in the figures). A main power socket 56 of the PSU 54 is accessed from the rear of the sound management device 1. The main power socket 56 receives a single power cord, to supply power to the entire sound management device

A hard disk drive 58 is in communication with the CPU 44 and is positioned adjacent the amplification circuitry 36 in the upper region 14 of the chassis 16 so as to be distant from the speakers 6. The rotating disk(s) of the hard disk drive 58 is orientated so that its rotating plane is not aligned with the magnetic field of the speakers 6, and is in various embodiments orthogonal thereto. The orientation of the hard disk drive 58 to the speakers 6 ensures that the rotating disk(s) is exposed to minimal magnetic interference from the speakers 6. Additionally, the hard disk drive 58 is secured to the chassis 16 using vibration-absorbing fixtures, such as rubber mounts. These mounts prevent, or at least reduce, the transmission of any vibrations generated by the speakers 6 to the hard disk drive 58.

A second PSU 60 is mounted on a side of the hard disk drive 58 using spacers 62, which provide space between the second PSU 60 and the hard disk drive 58 for the addition of a second hard disk drive, if required. The sole function of the second PSU 60 is to supply power to the amplifier circuitry 36. Power is supplied to the second PSU 60 from the first PSU 54 by way of a power cable (not shown). Having a second PSU 60, that is separate from the motherboard 46 and all of the motherboard's associated components, ensures that any noise generated by data processing operations is not fed to the amplifier circuitry 36 via the power supply.

A high-gain wireless USB adapter/dongle 64 is located above the second PSU 60 and is attached to the aerial 32. The high-gain wireless adapter/dongle 62 features a USB interface, which connects with the motherboard 46 to provide connection with, for example, a wireless Internet access point or a wireless local area network. The aerial 32 is mounted to the exterior of the wooden casing 2. This improves signal reception, in comparison to conventional desktop computers where the aerial is mounted on a metal casing, because interference from nearby metallic bodies is minimised.

The A/D 42, like most audio capturing devices, is vulnerable to interference to a greater or lesser extent. Digital interference can result in the degradation of the original analog sound signal in the converted digital sound signal. The A/D 42 is therefore positioned in an area of the sound management device remote from some or all of the CPU 44 and the other data management components so as to prevent or minimise the risk of digital interference from these components.

The positioning of the various components within the casing 2 also ensures that the temperature inside the casing 2 is maintained at a suitable operating temperature for all of the electronic components. A main air channel is provided within the chassis 16 extending from the air intake 8 to the exhaust fan 34. The boundary walls of the main air channel are defined by some of the external surfaces of the various components mounted in the chassis but may also include additional channel walls, where necessary. In particular, the motherboard 46 is exposed to, or at least is in thermal communication with, air flow in the main air channel. Also the rear of one or more of the speakers 6 forms part of a boundary wall of the main air channel or is physically connected to the boundary wall so that vibrations from the rear of the speakers 6 are transmitted directly or via the boundary wall to driven air flowing within the main air channel.

During use, the exhaust fan 34 draws air into the interior of the casing 2 via the air intake 8 and the openings 38 and 52. The air then circulates around the various components within the sound management device before exiting via the exhaust fan 34, positioned at the exposed rear surface of the chassis 16. The arrangement and size of the openings in the grill of the air intake 8 ensures that the velocity of the air entering the sound management device through the grill is sufficient to establish a cooling airflow that forcibly cools the various components contained within the sound management device, in particular the CPU 44 on the motherboard 46 and any optional device using the motherboard's PCI-E port. The openings in the grill of the air intake 8 are also sized to minimise any negative effect on the sound quality from the speakers 6. Thus, when the speakers are not in use but the data processor is active, air may be forced to flow through the casing 2 by the action of the exhaust fan 34.

As mentioned above, the speakers 6 also contribute to the cooling airflow by agitating the airflow when the speakers 6 are generating sounds. Where the rear of the speakers 6 form part of the boundary walls of the main air channel, the movement of the rear of the speakers 6 produces a pumping action within the main air channel arising from changes in volume within the main air channel. This pumping action causes air to be drawn in and expelled from the main air channel. Significantly, the larger action of the speakers 6 at higher decibels (when greater power is being consumed) produces a greater effect on the airflow within the casing 2.

The positioning of the optical disk drive 30, partially intersecting the main air channel between the speakers 6 and the exhaust fan 34, causes the optical disk drive 30 to act as a baffle at least partly shielding the exhaust fan 34 from excessive pressure variations arising from the larger action of the speakers 6 at higher decibels. It will be appreciated that the exhaust fan 34 can be adequately shielded by alternative means, where necessary.

The exhaust fan 34 may operate at all times when the data processor is active. Alternatively activation of the exhaust fan 34 may be triggered on demand, for example when the temperature within the casing or of an individual component exceeds a predetermined threshold. With this latter option, where the data processor and its associated components are not generating significant amounts of heat, the pumping or agitation action of the speakers 6 may be sufficient to control the temperature within the casing 2 without activation of the exhaust fan 34. Thus, with the speakers 6 in use, the data processor may on occasion be operated without the exhaust fan 34 being activated. This has the advantage of reducing overall power consumption of the sound management system.

Integration of the analog amplification system 1 with the computer as described above improves the latency of the electronic device due to the shorter physical connections between the amplifier circuitry and the data processor. The latency is further improved through the use of software that is optimised for use with the A/D 42, the CPU 44 and the motherboard 46.

A further advantage of the integration of the various components of the sound management device is that the data processor may be used to alter sound signals fed via the jack ports 44a and those signals may then be reproduced using the speakers 6. Thus, the analog amplifier circuitry 36 can be used, bypassing the data processor, or the data processor and the amplifier circuitry 36 can be used in series in which case the digital sound signals from the data processor are first converted from digital to analog before being fed to the amplifier circuitry 36.

Capturing sound via a microphone, for example, will produce different results depending upon the environment surrounding the microphone and in particular the size and materials within the room. The data processor may be used to emulate the sound characteristics of the analog amplifier circuitry 36 and thereby eliminate the effects that different rooms/microphone setups can produce.

Furthermore, once sound is recorded on a conventional computer the way the sound is recorded cannot be changed without re-recording the input sound again. With the sound management device described herein the sound may be recorded as a clean unchanged input sound signal. This enables a user to add effects such as ‘room type’, ‘emulate a microphone’, ‘change the sound characteristics virtually’ etc. after it has been recorded and then store an adapted version of the sound signal.

With the sound management device described herein the various components of the sound management device have been configured so as to produce the best possible sound quality and to minimise interference between the components making up the sound management device. This favourably compares with conventional sound equipment which requires the users to configure the various components of their sound system. Hence, the sound management device of the present disclosure offers a particularly convenient and compact and yet high performance device capable of sound amplification, manipulation and reproduction.

The jack I/O ports 36a also allow the speakers 6 to be connected to an external audio amplifier or headphones, regardless of whether or not the computer is operational.

The above description is of particular embodiments of the sound management system and it is to be understood that features of the embodiments may be altered without departing from the novel and inventive features embodied therein. For example, reference is made herein to particular types and numbers of fixtures and input and output ports. Different types and different numbers of fixtures and input and output ports may be used without departing from the present disclosure. Reference is also made to materials such as rubber, metal and wood but alternative materials offering similar performance characteristics may be substituted, where appropriate. The number and orientation of the openings illustrated in the figures may be similarly altered without departing from disclosure. Changes other than those itemised above are, of course, also envisaged, where appropriate or necessary.

Although the present disclosure has been described and illustrated in detail, it should be clearly understood that the same is by way of example only and it is not to be taken by way of limitation, the spirit and scope of the present disclosure being limited only by the terms of the appended claims.

1. A sound management device comprising a casing in which is mounted an analog amplification system, a data processor and at least one speaker, the analog amplification system being directly connected to the at least one speaker and also being connected to the data processor which, in turn, is connected to the at least one speaker, whereby the analog amplification system can be used in combination with or independently from the data processor to amplify an analog sound signal.

2. A sound management device as claimed in claim 1, wherein the casing comprises one or more air inlets and an exhaust fan, wherein the sound management device further comprises a first air channel provided within the casing, the first air channel extending from the one or more air inlets in the casing to the exhaust fan, with the rear of at least one speaker in contact with or forming part of a boundary wall of the first air channel to expose air in the first air channel to vibrations generated by the rear of the speaker and at least a part of the data processor being in thermal communication with the first air channel whereby heat generated by the data processor may be dissipated by means of air flow in the first air channel.

3. A sound management device as claimed in claim 2, wherein the at least one speaker and the exhaust fan are positioned on opposing sides of the casing.

4. A sound management device as claimed in claim 2, wherein the data processor includes a least one motherboard and the air flow path along the first air channel is arranged to be in thermal contact with at least part of the at least one motherboard.

5. A sound management device as claimed in claim 2, further comprising a baffle positioned in the first air channel between the at least one speaker and the exhaust fan for reducing the transmission of vibrations from the rear of the speaker to the exhaust fan.

6. A sound management device as claimed in claim 2, wherein one or more further air channels communicating with additional air inlets may be provided, the further air channels being interconnected with the first air channel.

7. A sound management device as claimed in claim 1, wherein the casing is made of wood.

8. A sound management device as claimed in claim 7, further comprising an antenna of a wireless adaptor seated on the wooden casing.

9. A sound management device as claimed in claim 1, wherein the latency of the sound management device is minimised by arranging the various components within the casing so as to minimise the amount and the length of cabling used and by selective configuration of the components.

10. A sound management device as claimed in claim 1, further comprising an A/D for interfacing between the analog amplification system and the data processor.

11. A sound management device as claimed in claim 10, wherein the A/D is positioned in the casing remote from at least some of the data processor and the other data management components.

12. A sound management device as claimed in claim 1, further comprising at least one I/O port connected directly to the analog amplification system whereby the analog amplification system is operational independently of the data processor.

13. A sound management device as claimed in claim 1, further comprising at least one I/O port connected to the data processor.
